(19) United States
(12) Patent Application Publication
(10) Pub. No.: US 2024/0260360 A1
(43) Pub. Date: Aug. 1, 2024

(54) DISPLAY DEVICE AND METHOD OF FABRICATING THE SAME

(71) Applicant: Samsung Display Co., LTD., Yongin-si (KR)

(72) Inventors: Duck Jung LEE, Yongin-si (KR); Hye Jin GWARK, Yongin-si (KR); Jae Ik KIM, Yongin-si (KR); Hwi KIM, Yongin-si (KR); Jung Sun PARK, Yongin-si (KR); Seung Yong SONG, Yongin-si (KR); Yeon Hwa LEE, Yongin-si (KR); Joon Gu LEE, Yongin-si (KR)

(73) Assignee: Samsung Display Co., LTD., Yongin-si (KR)

(21) Appl. No.: 18/520,673

(22) Filed: Nov. 28, 2023

(30) Foreign Application Priority Data
Jan. 27, 2023 (KR) 10-2023-0011203

(51) Int. Cl. H10K 59/131; H10K 59/12; H10K 59/122

(52) U.S. Cl. CPC H10K 59/131; H10K 59/1201; H10K 59/122

(57) ABSTRACT

A display device includes: a pixel circuit layer including a base layer, a pixel circuit, and a passivation layer including a well area and a protrusion area; and a light-emitting-element layer disposed on the pixel circuit layer, and including a light emitting element, and a connecting electrode, the light emitting element including a first electrode, a second electrode, and an emission part. The connecting electrode is disposed in the protrusion area, and at least a portion of the connecting electrode overlaps the well area and does not contact the passivation layer. The emission part includes a hole layer, an electron layer, and an emission layer. The hole layer connects the first electrode and the emission layer. The electron layer connects the second electrode and the emission layer. Each of the hole layer and the second electrode has an end portion on the connecting electrode.

### CROSS-REFERENCE TO RELATED APPLICATION(S)

This application claims priority to and benefits of Korean patent application No. 10-2023-0011203 under 35 U.S.C. § 119, filed on Jan. 27, 2023, in the Korean Intellectual Property Office, the entire contents of which are incorporated herein by reference.

### BACKGROUND

### 1. Technical Field

Various embodiments relate to a display device and a method of fabricating the display device.

### 2. Description of Related Art

With the development of information technology, the importance of a display device, which is a connection medium between a user and information, has been emphasized. The display device may include a light emitting element.

To enhance visibility of the display device, the reliability of an electrical signal to be supplied to a pixel in the display device has been important. For example, to prevent an electrical signal in the entirety of a display surface from being distorted, it is required to prevent an undesired resistance deviation from occurring.

Furthermore, it is necessary to electrically separate some components from each other so as to make it possible to supply separate electrical signals (e.g., anode signals) to two or more sub-pixels. A method using a separate structure has been taken into account, but an additional process is required, resulting in the excessively difficult process.

### SUMMARY

Various embodiments provide a display device capable of improving the display quality and a method of fabricating the display device capable of enhancing the process efficiency and reducing the process cost.

However, embodiments of the disclosure are not limited to those set forth herein. The above and other embodiments will become more apparent to one of ordinary skill in the art to which the disclosure pertains by referencing the detailed description of the disclosure given below.

In an embodiment, a display device may include: a pixel circuit layer including a base layer, a pixel circuit disposed on the base layer, and a passivation layer disposed on the pixel circuit and including a well area and a protrusion area; and a light-emitting-element layer disposed on the pixel circuit layer, and including a light emitting element including a first electrode, a second electrode, and an emission part between the first electrode and the second electrode, and a connecting electrode, the light emitting element. The connecting electrode may be disposed in the protrusion area, and at least a portion of the connecting electrode may overlap the well area in a plan view and may not contact the passivation layer. The emission part may include a hole layer, an electron layer, and an emission layer between the hole layer and the electron layer. The hole layer may electrically connect the first electrode and the emission layer to each other, and the electron layer may electrically connect the second electrode and the emission layer to each other. Each of the hole layer and the second electrode may have an end portion on the connecting electrode.

In an embodiment, the first electrode may be an anode electrode. The second electrode may be a cathode electrode. The pixel circuit may include a first power line and a second power line. The pixel circuit may be electrically connected to the first power line and the first electrode. The connecting electrode may be electrically connected to the second electrode and the second power line.

In an embodiment, the second power line may be electrically connected to the connecting electrode through a contactor formed in the passivation layer.

In an embodiment, the display device may further include a display area and a non-display area. The second power line may be disposed in the non-display area, and a portion of the connecting electrode may be disposed in a perimeter of the display area, and may be electrically connected to the second power line.

In an embodiment, the hole layer may include a hole injection layer and a hole transport layer. The electron layer may include an electron injection layer and an electron transport layer.

In an embodiment, the emission layer may include a first emission layer forming a first sub-pixel, and a second emission layer forming a second sub-pixel. The connecting electrode may be disposed in a boundary area between the first sub-pixel and the second sub-pixel.

In an embodiment, a first portion of the connecting electrode may surround the first emission layer, a second portion of the connecting electrode may surround the second emission layer, and the first portion and the second portion of the connecting electrode may be integral with each other.

In an embodiment, the connecting electrode may have a mesh shape, and form a closed loop surrounding an area.

In an embodiment, the light-emitting-element layer may include a pixel defining layer covering the first electrode and at least a portion of the connecting electrode. The pixel defining layer may expose a portion of the connecting electrode that is disposed in a peripheral portion of the emission layer, and may cover another portion of the connecting electrode.

In an embodiment, the pixel defining layer may include a first pixel defining layer and a second pixel defining layer. The first pixel defining layer may cover an end portion of the first electrode of the second sub-pixel, and may expose an end portion of the connecting electrode. The second pixel defining layer may cover an end portion of the first electrode of the first sub-pixel, and cover another end portion of the connecting electrode.

In an embodiment, the second pixel defining layer may have a width greater than a width of the first pixel defining layer.

In an embodiment, at least a portion of a lower surface of the connecting electrode may contact the pixel defining layer.

In an embodiment, the protrusion area may surround at least a portion of the well area. The protrusion area may include a first protrusion area in which the first electrode is disposed, and a second protrusion area in which the connecting electrode is disposed.

In an embodiment, the connecting electrode may include a protrusion. The protrusion may overlap the well area in a plan view. The passivation layer may form a curved area overlapping the protrusion in a plan view.

In an embodiment, at least a portion of the hole layer may be disposed on the protrusion. At least another portion of the hole layer may be disposed in the curved area that overlaps the protrusion in a plan view.

In an embodiment, at least a portion of the electron layer may be disposed on the protrusion. At least another portion of the electron layer may be disposed in the curved area that overlaps the protrusion in a plan view.

In an embodiment, at least a portion of the second electrode may be disposed on the protrusion. At least another portion of the second electrode may be disposed in the curved area that overlaps the protrusion in a plan view.

In an embodiment, the electron layer disposed in the curved area may cover the hole layer.

In an embodiment, the second electrode is electrically connected to a side surface of the connecting electrode.

In an embodiment, the first electrode may include a 1-1-th electrode, a 1-2-th electrode, and a 1-3-th electrode. The second electrode may contact the 1-2-th electrode.

In an embodiment, the 1-3-th electrode may protrude longer than the 1-1-th electrode and the 1-2-th electrode.

In an embodiment, each of the 1-1-th electrode and the 1-3-th electrode may include transparent conductive oxide. The 1-2-th electrode may include a reflective material. The 1-1-th electrode may be disposed on a surface of the 1-2-th electrode, and the 1-3-th electrode may be disposed on another surface of the 1-2-th electrode.

In an embodiment, the first electrode may be formed in a single layer including transparent conductive oxide.

In an embodiment, a display device may include sub-pixels including a first sub-pixel and a second sub-pixel. Each of the first and second sub-pixels may include: a pixel circuit layer including a base layer, a pixel circuit disposed on the base layer, and a passivation layer disposed on the pixel circuit; and a light-emitting-element layer disposed on the pixel circuit layer, and including a light emitting element including a first electrode, a second electrode, and an emission part between the first electrode and the second electrode, a pixel defining layer including a first pixel defining layer and a second pixel defining layer, and a connecting electrode. The emission part may include a first emission part in the first sub-pixel, and a second emission part in the second sub-pixel. The connecting electrode may be disposed between the first emission part and the second emission part. The first pixel defining layer may cover an end portion of the first electrode in the second emission part, and may expose an end portion of the connecting electrode. The second pixel defining layer may cover both an end portion of the first electrode in the first emission part, and another end portion of the connecting electrode.

In an embodiment, a method of fabricating a display device may include: forming a passivation layer on a bottom layer including a pixel circuit; patterning a first electrode and a connecting electrode on the passivation layer; etching the passivation layer; patterning a pixel defining layer on the first electrode and the connecting electrode; forming an emission part; and forming a second electrode on the emission part. The patterning of the pixel defining layer may include exposing at least a portion of each of the first electrode and the connecting electrode from the pixel defining layer. The etching of the passivation layer may include exposing at least a portion of a lower surface of the connecting electrode.

In an embodiment, the etching of the passivation layer may include forming a well area and a protrusion area of the passivation layer. The well area may include an under-cut portion on the lower surface of the connecting electrode.

In an embodiment, the emission part may include a hole layer, an electron layer, and an emission layer between the hole layer and the electron layer. The emission layer may include a first emission layer forming a first sub-pixel, and a second emission layer forming a second sub-pixel. The patterning of the pixel defining layer may include: patterning a first pixel defining layer; and patterning a second pixel defining layer. The first pixel defining layer may cover an end portion of the first electrode of the second sub-pixel, and may expose an end portion of the connecting electrode. The second pixel defining layer may cover an end portion of the first electrode of the first sub-pixel, and cover another end portion of the connecting electrode.

In an embodiment, the forming of the emission part may include: depositing a hole layer; patterning an emission layer on the hole layer; and the depositing of an electron layer. The depositing of the hole layer may include cutting the hole layer on an end portion of the connecting electrode.

In an embodiment, the forming of the second electrode may include cutting the second electrode on an end portion of the connecting electrode.

In an embodiment, the first electrode may include a 1-1-th electrode, a 1-2-th electrode on the 1-1-th electrode, and a 1-3-th electrode on the 1-2-th electrode. The connecting electrode may include a first connecting electrode, a second connecting electrode on the first connecting electrode, and a third connecting electrode on the second connecting electrode. The 1-1-th electrode and the first connecting electrode may be formed by a same process. The 1-2-th electrode and the second connecting electrode may be formed by a same process. The 1-3-th electrode and the third connecting electrode may be formed by a same process. Each of the 1-1-th electrode, the 1-3-th electrode, the first connecting electrode, and the third connecting electrode may include transparent conductive oxide. Each of the 1-2-th electrode and the second connecting electrode may include a reflective material.

In an embodiment, the 1-3-th electrode may have a thickness greater than a thickness of the 1-1-th electrode. The third connecting electrode may have a thickness greater than a thickness of the first connecting electrode. The third connecting electrode may protrude longer than the second connecting electrode.

In an embodiment, each of the first electrode and the connecting electrode may include transparent conductive oxide and may not include a reflective material. A dry etching process of the patterning of the first electrode and the connecting electrode and a dry etching process of removing at least a portion of the passivation layer may be successively performed.

### BRIEF DESCRIPTION OF THE DRAWINGS

FIG. 1 is a schematic plan view illustrating a display device in accordance with an embodiment.

FIG. 2 is a schematic sectional view illustrating a display device in accordance with an embodiment.

FIG. 3 is a schematic sectional view illustrating a light emitting element in accordance with an embodiment.

FIG. 4 is a schematic block diagram illustrating an electrical connection structure of a light emitting element in accordance with an embodiment.

FIG. 5 is a schematic plan view illustrating a display device in accordance with an embodiment.

FIG. 6 is a schematic sectional view illustrating a pixel circuit layer in accordance with an embodiment.

FIG. 7 is a schematic enlarged view showing area EA1 of FIG. 1.

FIGS. 8 and 9 are schematic sectional views taken along line A-A′ of FIG. 5, and illustrate a structure in accordance with a first embodiment.

FIGS. 10 and 11 are schematic sectional views taken along line A-A′ of FIG. 5, and illustrate a structure in accordance with a second embodiment.

FIG. 12 is a flowchart illustrating a method of fabricating the display device in accordance with an embodiment.

FIGS. 13 to 18 are schematic sectional views illustrating, by processes, the method of fabricating the display device in accordance with an embodiment.

### DETAILED DESCRIPTION OF THE EMBODIMENTS

In the following description, for the purposes of explanation, numerous specific details are set forth in order to provide a thorough understanding of various embodiments or implementations of the invention. As used herein “embodiments” and “implementations” are interchangeable words that are non-limiting examples of devices or methods disclosed herein. It is apparent, however, that various embodiments may be practiced without these specific details or with one or more equivalent arrangements. Here, various embodiments do not have to be exclusive nor limit the disclosure. For example, specific shapes, configurations, and characteristics of an embodiment may be used or implemented in another embodiment.

Unless otherwise specified, the illustrated embodiments are to be understood as providing features of the invention. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the invention.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the DR1-axis, the DR2-axis, and the DR3-axis are not limited to three axes of a rectangular coordinate system, such as the X, Y, and Z-axes, and may be interpreted in a broader sense. For example, the DR1-axis, the DR2-axis, and the DR3-axis may be perpendicular to one another, or may represent different directions that are not perpendicular to one another. Further, the X-axis, the Y-axis, and the Z-axis are not limited to three axes of a rectangular coordinate system, such as the x, y, and z axes, and may be interpreted in a broader sense. For example, the X-axis, the Y-axis, and the Z-axis may be perpendicular to one another, or may represent different directions that are not perpendicular to one another. For the purposes of this disclosure, “at least one of A and B” may be construed as understood to mean A only, B only, or any combination of A and B. Also, “at least one of X, Y, and Z” and “at least one selected from the group consisting of X, Y, and Z” may be construed as X only, Y only, Z only, or any combination of two or more of X, Y, and Z. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

As customary in the field, some embodiments are described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, and/or modules being implemented by microprocessors or other similar hardware, they may be programmed and controlled using software (e.g., microcode) to perform various functions discussed herein and may optionally be driven by firmware and/or software. It is also contemplated that each block, unit, and/or module may be implemented by dedicated hardware, or as a combination of dedicated hardware to perform some functions and a processor (e.g., one or more programmed microprocessors and associated circuitry) to perform other functions. Also, each block, unit, and/or module of some embodiments may be physically separated into two or more interacting and discrete blocks, units, and/or modules without departing from the scope of the invention. Further, the blocks, units, and/or modules of some embodiments may be physically combined into more complex blocks, units, and/or modules without departing from the scope of the invention.

Various embodiments relate to a display device and a method of fabricating the display device. Hereinafter, a display device and a method of fabricating the display device in accordance with an embodiment will be described with reference to the attached drawings.

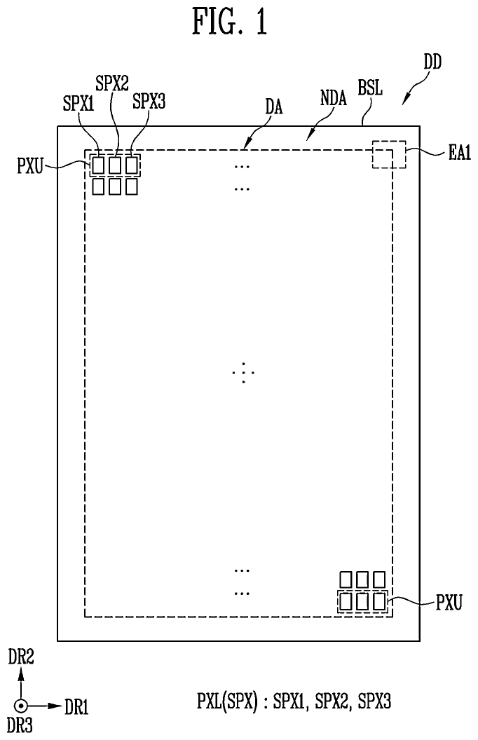

FIG. 1 is a schematic plan view illustrating a display device in accordance with an embodiment.

The display device DD may emit light. The display device DD may include a light emitting element LD. In an embodiment, the display device DD may be formed in various shapes. For example, the display device DD may be applied to a smart phone, a notebook computer, a table personal computer (PC), a wearable device (e.g., a head-mounted device, a smart watch, smart glasses, etc.), a television, or an in-vehicle infotainment system, and the like, and may be applied to various other embodiments.

Referring to FIG. 1, the display device DD may include a base layer BSL, and pixels PXL disposed on the base layer BSL. The display device DD may further include a driving circuit component (e.g., a scan driver and a data driver), lines, and pads which drive the pixels PXL.

The display device DD may include a display area DA and a non-display area NDA. The non-display area NDA may refer to an area other than the display area DA. The non-display area NDA may enclose (or surround) at least a portion of the display area DA.

The base layer BSL may form a base of the display device DD. The base layer BSL may be a rigid or flexible substrate or film. For example, the base layer BSL may be a rigid substrate made of glass or reinforced glass, a flexible substrate (or a thin film) formed of plastic or metal, or at least one insulating layer. The material and/or properties of the base layer BSL are not limited thereto. In an embodiment, the base layer BSL may be substantially transparent. Here, the words “substantially transparent” may mean that light can pass through the base layer BSL with a transmittance of a certain value or more. In an embodiment, the base layer BSL may be translucent or opaque. Furthermore, the base layer BSL may include reflective material according to an embodiment.

The display area DA may refer to an area in which the pixels PXL are disposed. The non-display area NDA may refer to an area in which the pixels PXL are not disposed. The driving circuit component, the lines, and the pads which are connected to the pixels PXL of the display area DA may be disposed in the non-display area NDA.

In an embodiment, the pixels PXL (or sub-pixels SPX) may be arranged according to a stripe or PENTILE™ arrangement structure. However, embodiments are not limited thereto.

In an embodiment, each pixel PXL may include a light emitting element LD. The pixel PXL (or sub-pixels SPX) may include a first sub-pixel SPX1, a second sub-pixel SPX2, and a third sub-pixel SPX3. At least one first sub-pixel SPX1, at least one second sub-pixel SPX2, and at least one third sub-pixel SPX3 may form a pixel unit PXU which emits various colors of light.

For example, each of the first sub-pixel SPX1, the second sub-pixel SPX2, and the third sub-pixel SPX3 may emit a color of light. For instance, the first sub-pixel SPX1 may be a red pixel that emits first color light (e.g., red light), the second sub-pixel SPX2 may be a green pixel that emits second color light (e.g., green light), and the third sub-pixel SPX3 may be a blue pixel that emits third color light (e.g., blue light). The color, type, and/or number of the first sub-pixel SPX1, the second sub-pixel SPX2, and the third sub-pixel SPX3 which form each pixel unit PXU is not limited thereto.

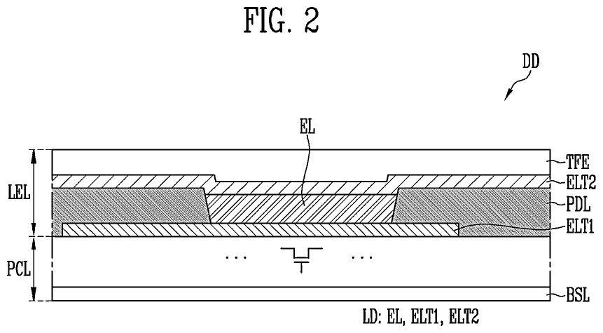

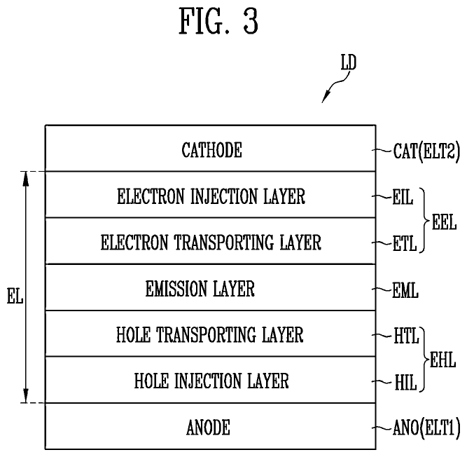

FIG. 2 is a schematic sectional view illustrating a display device in accordance with an embodiment. FIG. 3 is a schematic sectional view illustrating a light emitting element in accordance with an embodiment.

Referring to FIGS. 2 and 3, the display device DD may include a pixel circuit layer PCL and a light-emitting-element layer LEL.

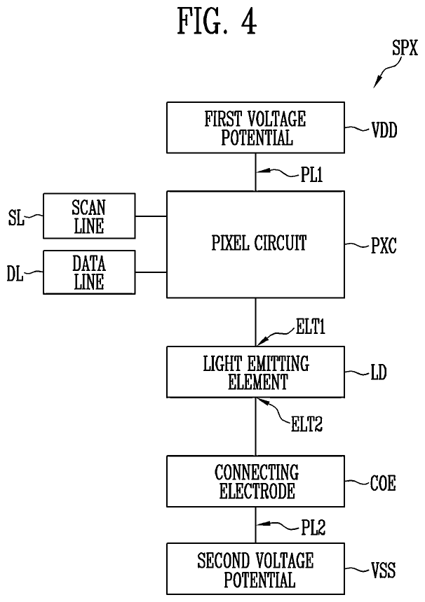

The pixel circuit layer PCL may be a layer including a pixel circuit PXC (refer to FIG. 4) that drives the light emitting elements LD. The pixel circuit layer PCL may include a base layer BSL, conductive layers forming pixel circuits, and insulating layers disposed between the conductive layers.

In an embodiment, the pixel circuit PXC may include a thin film transistor, and may be connected (e.g., electrically connected) to the light emitting elements LD and provide electrical signals to the light emitting elements LD such that the light emitting elements LD may emit light.

The light-emitting-element layer LEL may be disposed on the pixel circuit layer PCL. In an embodiment, the light-emitting-element layer LEL may include a light emitting element LD, a pixel defining layer PDL, and an encapsulation layer TFE.

The light emitting element LD may be disposed on the pixel circuit layer PCL. In an embodiment, the light emitting element LD may include a first electrode ELT1, an emission part EL, and a second electrode ELT2. In an embodiment, the emission part EL may be disposed in an area defined by the pixel defining layer PDL. A surface of the emission part EL may be connected (e.g., electrically connected) to the first electrode ELT1. Another surface (e.g., opposite surface) of the emission part EL may be connected (e.g., electrically connected) to the second electrode ELT2.

The first electrode ELT1 may be an anode electrode ANO for the emission part EL. The second electrode ELT2 may be a cathode electrode CAT for the emission part EL. In an embodiment, the first electrode ELT1 and the second electrode ELT2 may include conductive material. For example, the first electrode ELT1 may include conductive material having reflectibility, and the second electrode ELT2 may include transparent conductive material, but embodiments are not limited thereto.

The emission part EL may have a multilayer thin-film structure including a light generation layer (e.g., an emission layer EML). The emission part EL may include a hole injection layer HIL that injects holes, a hole transport layer HTL which has excellent hole transportability and restrain movement of uncombined electrons in the emission layer EML so as to increase the opportunity of recombination between holes and electrons, an emission layer EML that emits light by recombination between injected electrodes and holes, an electron transport layer ETL that smoothly transports electrons to the emission layer EML, and an electron injection layer EIL that injects electrons. The emission part EL may emit light based on an electrical signal provided from the anode electrode ANO (e.g., the first electrode ELT1) and the cathode electrode CAT (e.g., the second electrode ELT2).

The pixel defining layer PDL may be disposed on the pixel circuit layer PCL, and may define a position at which the emission part EL is to be disposed. The pixel defining layer PDL may include organic material. In an embodiment, the pixel defining layer PDL may be formed of one or more selected from the group consisting of acryl resin, epoxy resin, phenol resin, polyamide resin, and polyimide resin. However, embodiments are not limited thereto.

The encapsulation layer TFE may be disposed on the light emitting element LD (e.g., the second electrode ELT2). The encapsulation layer TFE may offset a step difference formed by the light emitting element LD and the pixel defining layer PDL. The encapsulation layer TFE may include insulating layers that covers the light emitting element LD. In an embodiment, the encapsulation layer TFE may have a structure formed by alternately stacking inorganic layers and organic layers. In an embodiment, the encapsulation layer TFE may be formed of a thin film encapsulation layer.

FIG. 4 is a schematic block diagram illustrating an electrical connection structure of the light emitting element in accordance with an embodiment. For example, FIG. 4 illustrates an electrical connection structure including a pixel circuit PXC corresponding to each sub-pixel SPX.

Referring to FIG. 4, the sub-pixel SPX may include a pixel circuit PXC that emits the light emitting element LD.

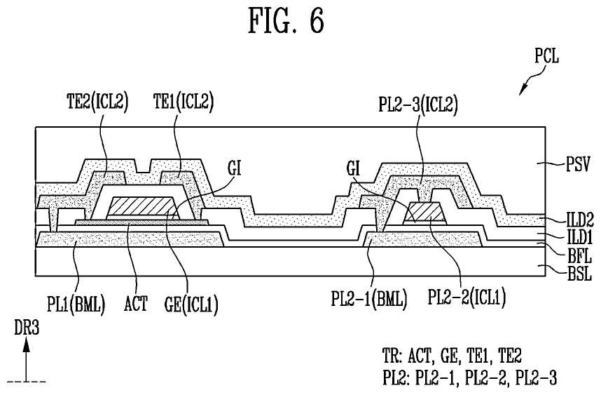

The pixel circuit PXC may include one or more circuit elements. For instance, the pixel circuit PXC may include three transistors, and a storage capacitor. For instance, the pixel circuit PXC may include a driving transistor TR (refer to FIG. 6), a switching transistor, and a storage capacitor. However, embodiments are not limited thereto.

The pixel circuit PXC may be connected (e.g., electrically connected) to a scan line SL and a data line DL. The scan line SL may supply a scan signal to the pixel circuit PXC. In an embodiment, the scan line SL may be connected (e.g., electrically connected) to a gate electrode of the switching transistor of the pixel circuit PXC. The light emitting element LD may emit light corresponding to a data signal provided from the data line DL.

The pixel circuit PXC may be connected (e.g., electrically connected) to a first power line PL1 and a second power line PL2. For example, the first electrode ELT1 of the light emitting element LD may be connected (e.g., electrically connected) to the pixel circuit PXC and the first power line PL1. The second electrode ELT2 of the light emitting element LD may be connected (e.g., electrically connected) to the second power line PL2.

Power of the first power line PL1 and power of the second power line PL2 may have different potentials. For example, the power of the first power line PL1 may correspond to high-potential pixel power, which is supplied with power from a first voltage source VDD. The power of the second power line PL2 may correspond to low-potential pixel power, which is supplied with power from a second voltage source VSS. A difference in potential between the power of the first power line PL1 and the power of the second power line PL2 may be set to a value substantially equal to or greater than the threshold voltage of the light emitting elements LD.

The first power line PL1 may be connected (e.g., electrically connected) to the pixel circuit PXC (e.g., the driving transistor TR). The second power line PL2 may be connected (e.g., electrically connected) to the cathode electrode (e.g., the second electrode ELT2) of the light emitting element LD.

In an embodiment, the second power line PL2 may be connected (e.g., electrically connected) to the second electrode ELT2 through a connecting electrode COE. For example, the connecting electrode COE may connect (e.g., electrically connect) the second electrode ELT2 and the second power line PL2 to each other. Detailed description of the connecting electrode COE will be made below herein.

Each light emitting element LD may be connected in a forward direction between the first power line PL1 and the second power line PL2, and may form a valid light source. The valid light sources may be grouped to form the light emitting elements LD of the sub-pixel SPX.

The light emitting elements LD may emit light at a luminance corresponding to driving current supplied thereto through the pixel circuit PXC. During each frame period, the pixel circuit PXC may supply driving current corresponding to a data signal to the light emitting element LD. The light emitting element LD may emit light at a luminance corresponding to driving current that flows therethrough.

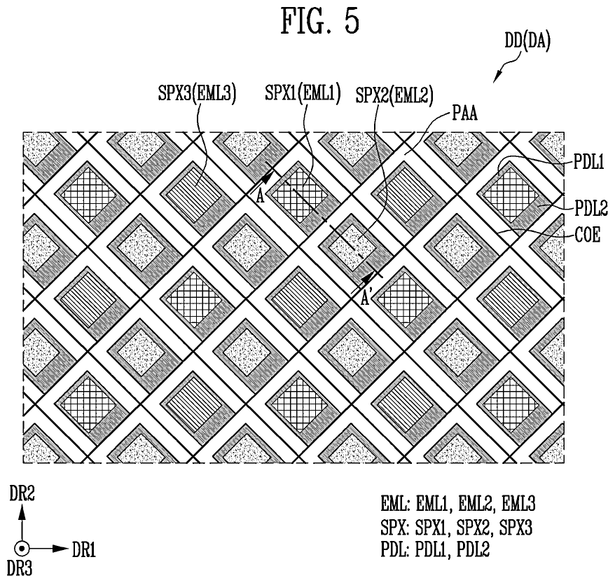

FIG. 5 is a schematic plan view illustrating a display device in accordance with an embodiment. FIG. 5 illustrates a portion of the display area DA. FIG. 5 illustrates a position relationship in a plan view between the emission layers EML, the pixel defining layer PDL, and the connecting electrode COE that are distinguished from each other to form sub-pixels SPX.

Referring to FIG. 5, the emission layer EML, the pixel defining layer PDL, and the connecting electrode COE may be disposed in the display area DA.

The emission layer EML may include a first emission layer EML1 provided to form a first sub-pixel SPX1 that emits a first color of light, a second emission layer EML2 provided to form a second sub-pixel SPX2 that emits a second color of light, and a third emission layer EML3 provided to form a third sub-pixel SPX3 that emits a third color of light.

For example, the emission layers EML may be selectively disposed in some areas in the display area DA, and thus define areas from which different colors of light are respectively emitted. In an embodiment, the first emission layer EML1 may form a first light emitting element that emits a first color of light. The second emission layer EML2 may form a second light emitting element that emits a second color of light. The third emission layer EML3 may form a third light emitting element that emits a third color of light.

Each of the emission layers EML may be disposed in an area enclosed (or surround) by the connecting electrode COE. For example, the number of pattern areas PAA defined by patterning the connecting electrode COE in such a way that the connecting electrode COE encloses (or surrounds) the pattern areas PAA in at least some areas of the display area DA may be the same as the number of emission layers EML (or defined sub-pixels SPX). However, embodiments are not limited thereto. The connecting electrode COE may be disposed to enclose (or surround) two or more emission layers EML.

The connecting electrode COE may be a connector that supplies a cathode signal to the light emitting element LD. For example, the connecting electrode COE may be connected (e.g., electrically connected) to the second electrode ELT2.

The connecting electrode COE may be disposed in a peripheral portion of each of the emission layers EML. The connecting electrode COE may enclose (or surround) at least a portion of each of the emission layers EML in a plan view. The connecting electrode COE may be disposed in a boundary area between the emission layers EML (or the sub-pixels SPX) adjacent to each other.

The connecting electrode COE may be disposed in a mesh shape. For example, the connecting electrode COE may be patterned to enclose (or surround) each of two or more areas. The connecting electrode COE may form a closed-loop. The connecting electrode COE may be patterned to enclose (or surround) an area, thus defining a pattern area PAA. The pattern areas PAA may have respective shapes corresponding to each other. In an embodiment, the pattern areas PAA may have the same shape as each other. In an embodiment, the connecting electrode COE may enclose (or surround) an emission layer EML or two or more emission layers EML.

The shapes of the pattern areas PAA and the shapes of the emission layers EML may correspond to each other in a plan view. For example, each of the shapes of the pattern areas PAA and the emission layers EML may have a rhombus shape. Each of the pattern areas PAA may have a trapezoidal shape. However, embodiments are not limited thereto.

The connecting electrodes COE may be integral with each other. For example, the connecting electrodes COE may be deposited and patterned by the same process. The connecting electrodes COE may be connected (e.g., electrically connected) to each other, and may be supplied with the same electrical signal (e.g., a cathode signal). For example, a first portion of the connecting electrode COE may enclose (or surround) the first sub-pixel SPX1 (e.g., the first emission layer EML1). A second portion of the connecting electrode COE may enclose (or surround) the second sub-pixel SPX2 (e.g., the second emission layer EML2). The first portion and the second portion of the connecting electrode COE may be integral with each other.

The pixel defining layer PDL may be disposed in a peripheral portion of each of the emission layers EML. The pixel defining layer PDL may enclose (or surround) at least a portion of each of the emission layers EML. In an embodiment, the pixel defining layer PDL may overlap the emission layers EML in a plan view. The pixel defining layer PDL may overlap the connecting electrode COE in a plan view.

The pixel defining layer PDL may have different widths in the pattern area PAA in a plan view. The pixel defining layer PDL may contact any one line of a plurality of lines of the connecting electrode COE that forms each pattern area PAA, and may not contact the other lines of the plurality of lines. The pixel defining layer PDL may expose a portion of the connecting electrode COE that is disposed in the peripheral portion of the emission layer EML, and may cover another portion of the connecting electrode COE that is disposed in the peripheral portion of the emission layer EML.

For example, the pixel defining layer PDL may include a first pixel defining layer PDL1 and a second pixel defining layer PDL2. The first pixel defining layer PDL1 may have a width less than that of the second pixel defining layer PDL2 in a plan view. The first pixel defining layer PDL1 may be spaced (e.g., physically spaced) apart from an adjacent connecting electrode COE. The second pixel defining layer PDL2 may contact (e.g., physically contact) an adjacent connecting electrode COE.

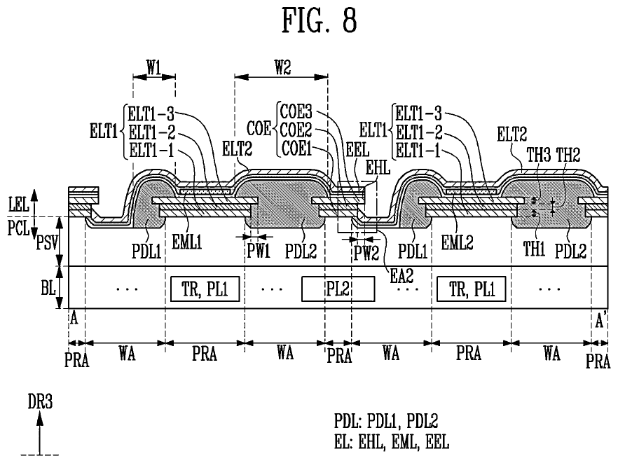

In an embodiment, in an area adjacent to the connecting electrode COE as an area corresponding to the first pixel defining layer PDL1, a hole layer EHL and the cathode electrode CAT each may have an end portion (or an edge area). In an area adjacent to the connecting electrode COE as an area corresponding to the second pixel defining layer PDL2, the hole layer EHL and the cathode electrode CAT each may not have an end portion. Detailed description pertaining to the foregoing will be made below with reference to FIG. 8.

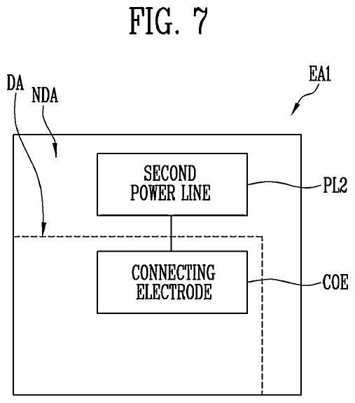

The pixel circuit layer PCL in accordance with an embodiment will be described with reference to FIGS. 6 and 7.

FIG. 6 is a schematic sectional view illustrating the pixel circuit layer PCL in accordance with an embodiment. FIG. 6 illustrates a first connection structure between the second power line PL2 and the connecting electrode COE. For example, FIG. 6 illustrates a structure in which the connecting electrode COE is connected (e.g., electrically connected) to the second power line PL2 through a contactor formed in the pixel circuit layer PCL. FIG. 6 is a schematic sectional view illustrating the driving transistor TR and the second power line PL2 in accordance with an embodiment.

FIG. 7 is a schematic enlarged view illustrating area EA1 of FIG. 1. FIG. 7 is a schematic plan view illustrating a connection relationship between the second power line PL2 and the connecting electrode COE. FIG. 7 schematically illustrates a second connection structure between the second power line PL2 and the connecting electrode COE. For example, FIG. 7 illustrates a structure in which the connecting electrode COE is connected (e.g., electrically connected) to the second power line PL2 formed in the non-display area NDA.

Referring to FIG. 6, the pixel circuit layer PCL may include the first power line PL1, the second power line PL2, and the driving transistor TR. The pixel circuit layer PCL may include an auxiliary bottom electrode layer BML, a buffer layer BFL, an active layer ACT, a gate insulating layer GI, a first interlayer conductive layer ICL1, a first interlayer insulating layer ILD1, a second interlayer conductive layer ICL2, a second interlayer insulating layer ILD2, and a passivation layer PSV. The auxiliary bottom electrode layer BML, the active layer ACT, the first interlayer conductive layer ICL1, and the second interlayer conductive layer ICL2 may be patterned on the base layer BSL so that the first power line PL1, the second power line PL2, and the driving transistor TR may be formed.

The auxiliary bottom electrode layer BML may be disposed on the base layer BSL, and may form the first power line PL1 and a 2-1-th power line PL2-1.

The first power line PL1 may be connected (e.g., electrically connected) to the driving transistor TR (e.g., a second transistor electrode TE2).

The 2-1-th power line PL2-1 may form a portion of the second power line PL2. The 2-1-th power line PL2-1 may be connected (e.g., electrically connected) to a 2-3-th power line PL2-3.

The auxiliary bottom electrode layer BML may include one or more selected from the group of gold (Au), silver (Ag), aluminum (Al), molybdenum (Mo), chrome (Cr), titanium (Ti), nickel (Ni), neodymium (Nd), copper (Cu), and platinum (Pt). However, embodiments are not limited thereto.

The buffer layer BFL may be disposed on the auxiliary bottom electrode layer BML and the base layer BSL. The buffer layer BFL may cover the auxiliary bottom electrode layer BML.

The buffer layer BFL may prevent impurities from diffusing (or permeating) into the active layer ACT, or may prevent water from permeating the active layer ACT. In an embodiment, the buffer layer BFL may include one or more selected from the group consisting of silicon nitride (SiNₓ), silicon oxide (SiOₓ), silicon oxynitride (SiOₓN_{y}), and aluminum oxide (AlOₓ). However, embodiments are not limited thereto.

The active layer ACT may be disposed on the buffer layer BFL. The active layer ACT may form a portion of an active component of the driving transistor TR. The active layer ACT may include a semiconductor. For example, the active layer ACT may include at least one selected from the group consisting of polysilicon, low temperature polycrystalline silicon (LTPS), amorphous silicon, and an oxide semiconductor. The active layer ACT may form a channel of the driving transistor TR. At least a portion of the active layer ACT may be doped with an impurity.

The gate insulating layer GI may be disposed on the buffer layer BFL and the active layer ACT. The gate insulating layer GI may be disposed between a gate electrode GE of the driving transistor TR and the active layer ACT.

The gate insulating layer GI may include one or more selected from the group consisting of silicon nitride (SiNₓ), silicon oxide (SiOₓ), silicon oxynitride (SiOₓN_{y}), and aluminum oxide (AlOₓ). However, embodiments are not limited thereto.

The first interlayer conductive layer ICL1 may be disposed on the gate insulating layer GI (or the buffer layer BFL). The first interlayer conductive layer ICL1 may form the gate electrode GE of the driving transistor TR and a 2-2-th power line PL2-2.

The first interlayer conductive layer ICL1 may include one or more selected from the group of gold (Au), silver (Ag), aluminum (Al), molybdenum (Mo), chrome (Cr), titanium (Ti), nickel (Ni), neodymium (Nd), copper (Cu), and platinum (Pt). However, embodiments are not limited thereto.

The gate electrode GE may be disposed to correspond to (or overlap) a position of the channel area of the active layer ACT of the driving transistor TR.

The 2-2-th power line PL2-2 may form a portion of the second power line PL2. The 2-2-th power line PL2-2 may be connected (e.g., electrically connected) to the 2-3-th power line PL2-3.

The first interlayer insulating layer ILD1 may be disposed on the first interlayer conductive layer ICL1. The first interlayer insulating layer ILD1 may cover the first interlayer conductive layer ICL1.

The first interlayer insulating layer ILD1 may include one or more selected from the group consisting of silicon nitride (SiNₓ), silicon oxide (SiOₓ), silicon oxynitride (SiOₓN_{y}), and aluminum oxide (AlOₓ). However, embodiments are not limited thereto.

The second interlayer conductive layer ICL2 may be disposed on the second interlayer insulating layer ILD2. The second interlayer conductive layer ICL2 may form first and second transistor electrodes TE1 and TE2 of the driving transistor TR and the 2-3-th power line PL2-3.

The second interlayer conductive layer ICL2 may include one or more selected from the group of gold (Au), silver (Ag), aluminum (Al), molybdenum (Mo), chrome (Cr), titanium (Ti), nickel (Ni), neodymium (Nd), copper (Cu), and platinum (Pt). However, embodiments are not limited thereto.

The first and second transistor electrodes TE1 and TE2 may form a source electrode or a drain electrode of the driving transistor TR. For example, the first transistor electrode TE1 may be a source electrode, and the second transistor electrode TE2 may be a drain electrode.

The 2-3-th power line PL2-3 may form a portion of the second power line PL2. For example, the 2-3-th power line PL2-3 may be connected (e.g., electrically connected) to the connecting electrode COE. For example, the 2-3-th power line PL2-3 and the connecting electrode COE may be connected (e.g., electrically connected) to each other through a contactor formed in the passivation layer PSV. Hence, power supplied from the second power line PL2 may be applied to the connecting electrode COE.

The second interlayer insulating layer ILD2 may be disposed on the second interlayer conductive layer ICL2. The second interlayer insulating layer ILD2 may cover the second interlayer conductive layer ICL2.

The second interlayer insulating layer ILD2 may include one or more selected from the group consisting of silicon nitride (SiNₓ), silicon oxide (SiOₓ), silicon oxynitride (SiOₓN_{y}), and aluminum oxide (AlOₓ). However, embodiments are not limited thereto.

The passivation layer PSV may be disposed on the second interlayer insulating layer ILD2. In an embodiment, the passivation layer PSV may be a via layer. The passivation layer PSV may include organic material. For example, the organic material may include one or more selected from the group consisting of acrylic resin, epoxy resin, phenol resin, polyamide resin, polyimide resin, polyester resin, polyphenylene sulfide resin, and benzocyclobutene (BCB). However, embodiments are not limited thereto.

Referring to FIG. 7, in an embodiment, the connecting electrode COE may be supplied with power through the second power line PL2 disposed in the non-display area NDA. For example, the connecting electrode COE in the display area DA may be adjacent to the second power line PL2 with a proximity area interposed between the connecting electrode COE and the second power line PL2, the proximity area being formed between the display area DA and the non-display area NDA. The connecting electrode COE that is adjacent to the perimeter of the display area DA may be connected (e.g., electrically connected) to the second power line PL2 in the non-display area NDA. As described above, the connecting electrodes COE in the display area DA may be connected (e.g., electrically connected) to each other, so that the power provided from the second power line PL2 may be applied to the entirety of the display area DA.

A cross-sectional structure of the display device DD in accordance with an embodiment will be described with reference to FIGS. 8 to 11.

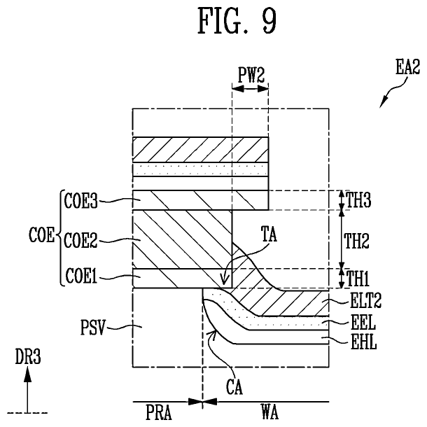

A display device DD in accordance with a first embodiment will be described with reference to FIGS. 8 and 9.

FIGS. 8 and 9 illustrate the display device DD in accordance with the first embodiment. FIGS. 8 and 9 are schematic sectional views taken along line A-A′ of FIG. 5, and illustrate a structure in accordance with the first embodiment. FIG. 9 is a schematic enlarged view of area EA2 of FIG. 8.

FIG. 8 schematically illustrates layers disposed under the passivation layer PSV in the pixel circuit layer PCL as a bottom layer BL. FIG. 8 illustrates the first emission layer EML1 and the second emission layer EML2 among the emission layers EML. For convenience of explanation, each of the first emission layer EML1 and the second emission layer EML2 may also be referred to an emission layer EML, and technical characteristics thereof will be described. The technical characteristics to be described may also be applied to the third emission layer EML3 in a similar scheme/manner.

The passivation layer PSV may be disposed on the bottom layer BL, and may include a well area (or well/recess portion) WA and a protrusion area (or protrusion portion) PRA. For example, the protrusion area PRA may be an area other than the well area WA. The protrusion area PRA may include a first protrusion area in which the first electrode ELT1 is disposed, and a second protrusion area in which the connecting electrode COE is disposed.

The well area WA may be an area formed by etching at least a portion of the passivation layer PSV after the passivation layer PSV is deposited. The well area WA may be an area formed by recessing a portion of the passivation layer PSV. The well area WA may enclose (or surround) at least a portion of the protrusion area PRA. The protrusion area PRA may enclose (or surround) at least a portion of the well area WA.

In an embodiment, a width of the well area WA may range from about 500 Å to about 2000 Å. However, embodiments are not limited thereto.

The protrusion area PRA may be an area defined by forming the well area WA. The protrusion area PRA may enclose (or surround) at least a portion of the well area WA.

The protrusion area PRA may provide a base surface on which the first electrode ELT1 or the connecting electrode COE is disposed. The first electrode ELT1 may not be disposed in the well area WA. The connecting electrode COE may not be disposed in the well area WA.

The first electrode ELT1 may contact the passivation layer PSV in the protrusion area PRA. The first electrode ELT1 may not contact the passivation layer PSV in the well area WA. The connecting electrode COE may contact the passivation layer PSV in the protrusion area PRA. The connecting electrode COE may not contact the passivation layer PSV in the well area WA.

At least a portion of a lower surface of the first electrode ELT1 may contact the pixel defining layer PDL. At least a portion of a lower surface of the connecting electrode COE may contact the pixel defining layer PDL.

The first electrode ELT1 and the connecting electrode COE may have the same layer structure, and may be formed as same layers. For example, the first electrode ELT1 and the connecting electrode COE may be deposited and patterned by the same process. The first electrode ELT1 and the connecting electrode COE may have a layer structure including the same material.

For example, the first electrode ELT1 may include a 1-1-th electrode ELT1-1, a 1-2-th electrode ELT1-2, and a 1-3-th electrode ELT1-3. The connecting electrode COE may include a first connecting electrode COE1, a second connecting electrode COE2, and a third connecting electrode COE3.

The 1-1-th electrode ELT1-1 and the first connecting electrode COE1 may be patterned by the same process, and may include the same material. The 1-2-th electrode ELT1-2 and the second connecting electrode COE2 may be patterned by the same process, and may include the same material. The 1-3-th electrode ELT1-3 and the third connecting electrode COE3 may be patterned by the same process, and may include the same material.

In an embodiment, as the connecting electrode COE, which electrically connects the second power line PL2 and the second electrode ELT2 to each other, is formed by the same process by which the first electrode ELT1 is formed, a separate/additional process for fabricating the connecting electrode COE may not be needed or may be omitted.

The 1-1-th electrode ELT1-1 and the first connecting electrode COE1 may be respectively disposed under the 1-2-th electrode ELT1-2 and the second connecting electrode COE2. The 1-1-th electrode ELT1-1 and the first connecting electrode COE1 may include transparent conductive oxide (TCO) having a relatively high work function so that holes may be readily injected into the emission layer EML. For example, the 1-1-th electrode ELT1-1 and the first connecting electrode COE1 may include indium tin oxide (ITO).

The 1-2-th electrode ELT1-2 may be disposed between the 1-1-th electrode ELT1-1 and the 1-3-th electrode ELT1-3. The second connecting electrode COE2 may be disposed between the first connecting electrode COE1 and the third connecting electrode COE3. The 1-2-th electrode ELT1-2 and the second connecting electrode COE2 each may be a reflective layer to enhance emission efficiency, and may include reflective material. For example, the 1-2-th electrode ELT1-2 and the second connecting electrode COE2 may include silver (Ag).

The 1-3-th electrode ELT1-3 and the third connecting electrode COE3 may be respectively disposed on the 1-2-th electrode ELT1-2 and the second connecting electrode COE2. The 1-3-th electrode ELT1-3 and the third connecting electrode COE3 may include transparent conductive oxide (TCO) having a relatively high work function so that holes may be readily injected into the emission layer EML. For example, the 1-3-th electrode ELT1-3 and the third connecting electrode COE3 may include indium tin oxide (ITO).

The connecting electrode COE and the passivation layer PSV may form an under-cut structure/portion or may have an under-cut shape. For example, at least a portion of the connecting electrode COE may protrude from a surface of the passivation layer PSV in the protrusion area PRA. For example, the first connecting electrode COE1 may protrude outward from an upper surface of the passivation layer PSV in the protrusion area PRA. The second connecting electrode COE2 may protrude outward from the upper surface of the passivation layer PSV in the protrusion area PRA. The third connecting electrode COE3 may protrude outward from the upper surface of the passivation layer PSV in the protrusion area PRA.

The connecting electrode COE may include a protrusion TA. The protrusion TA may not contact the passivation layer PSV. For example, the protrusion TA may be a portion of the connecting electrode COE that further protrudes from the upper surface of the passivation layer PSV. In an embodiment, the connecting electrode COE may further include an additional layer (e.g., an organic layer or an inorganic layer) provided to form the protrusion structure.

The protrusion TA may not overlap the protrusion area PRA in a plan view, and may overlap the well area WA. Hence, the passivation layer PSV may include a curved area CA, a portion of which is recessed from the end portion of the connecting electrode COE. The curved area CA may overlap the protrusion TA in a plan view.

In an embodiment, a thickness TH2 of the second connecting electrode COE2 may be greater than a thickness TH1 of the first connecting electrode COE1 and a thickness TH3 of the third connecting electrode COE3. In an embodiment, the thickness TH3 of the third connecting electrode COE3 may be greater than the thickness TH1 of the first connecting electrode COE1. In an embodiment, the first connecting electrode COE1 may have a thickness TH1 in a range of about 50 μm to about 80 μm. The second connecting electrode COE2 may have a thickness TH2 in a range of about 900 μm to about 1100 μm. The third connecting electrode COE3 may have a thickness TH3 in a range of about 50 μm to about 80 μm. However, embodiments are not limited thereto.

The first electrode ELT1 and the passivation layer PSV may form an under-cut structure/portion or may have an under-cut shape. For example, a portion of the first electrode ELT1 may protrude from a surface of the passivation layer PSV in the protrusion area PRA. For example, the 1-1-th electrode ELT1-1 may protrude outward from the upper surface of the passivation layer PSV in the protrusion area PRA. The 1-2-th electrode ELT1-2 may protrude outward from the upper surface of the passivation layer PSV in the protrusion area PRA. The 1-3-th electrode ELT1-3 may protrude outward from the upper surface of the passivation layer PSV in the protrusion area PRA. Hence, in a plan view, a portion of the first electrode ELT1 may not overlap the protrusion area PRA, may overlap the well area WA, and may not contact the passivation layer PSV.

The 1-3-th electrode ELT1-3 may protrude farther (or longer) than the 1-1-th electrode ELT1-1 and the 1-2-th electrode ELT1-2 in an edge direction. For example, the 1-3-th electrode ELT1-3 may have a surface area greater than each of the 1-1-th electrode ELT1-1 and the 1-2-th electrode ELT1-2. At least a portion of the 1-3-th electrode ELT1-3 may not be covered with/by the 1-2-th electrode ELT1-2.

The third connecting electrode COE3 may protrude farther (or longer) than the first connecting electrode COE1 and the second connecting electrode COE2 in the edge direction. For example, the third connecting electrode COE3 may have a surface area greater than that of each of the first connecting electrode COE1 and the second connecting electrode COE2. At least a portion of the third connecting electrode COE3 may not be covered with/by the second connecting electrode COE2.

In an embodiment, a width PW1 of an area by which the 1-3-th electrode ELT1-3 protrudes farther (or longer) than the 1-2-th electrode ELT1-2 may range from about 0.2 μm to about 0.6 μm. In an embodiment, a width PW2 of an area by which the third connecting electrode COE3 protrudes farther (or longer) than the second connecting electrode COE2 may range from about 0.2 μm to about 0.6 μm.

In an embodiment, a thickness TH2 of the 1-2-th electrode ELT1-2 may be greater than a thickness TH1 of the 1-1-th electrode ELT1-1 and a thickness TH3 of the 1-3-th electrode ELT1-3. In an embodiment, the thickness TH3 of the 1-3-th electrode ELT1-3 may be greater than the thickness TH1 of the 1-1-th electrode ELT1-1. In an embodiment, the 1-1-th electrode ELT1-1 may have a thickness TH1 in a range of about 50 μm to about 80 μm. The 1-2-th electrode ELT1-2 may have a thickness TH2 in a range of about 900 μm to about 1100 μm. The 1-3-th electrode ELT1-3 may have a thickness TH3 in a range of about 50 μm to about 80 μm. However, embodiments are not limited thereto.

The pixel defining layer PDL may cover edge areas of the first electrode ELT1 and the connecting electrode COE. For example, the first pixel defining layer PDL1 may cover a first end portion of the first electrode ELT1. The second pixel defining layer PDL2 may cover a second end portion of the first electrode ELT1, and may cover a first end portion of the connecting electrode COE.

The pixel defining layer PDL may expose a second end portion of the connecting electrode COE. For example, at least a portion of the connecting electrode COE may not be covered with/by the pixel defining layer PDL. Hence, a portion (e.g., a hole layer EHL and an electron layer EEL) of the emission part EL and a portion of the second electrode ELT2 may be disposed on the connecting electrode COE. For example, the hole layer EHL may contact the portion of the connecting electrode COE that is exposed from the pixel defining layer PDL.

The first pixel defining layer PDL1 may cover (e.g., partially cover) a portion of the well area WA. The second pixel defining layer PDL2 may cover the entirety of the corresponding well area WA. In an embodiment, the first pixel defining layer PDL1 may have a first width W1, and the second pixel defining layer PDL2 may have a second width W2. Here, the second width W2 may be greater than the first width W1.

In an embodiment, the pixel defining layer PDL may selectively expose a portion of the connecting electrode COE. Hence, in the case where the second electrode ELT2 is subsequently formed, at least a portion of the second electrode ELT2 may be cut in an area between the adjacent sub-pixels SPX, and the second electrode ELT2 may be connected (e.g., electrically connected) to the connecting electrode COE.

Therefore, the second electrode ELT2 for each sub-pixel SPX may be connected (e.g., electrically connected) to the connecting electrode COE adjacent thereto, and may be spaced (e.g., physically spaced) from the second electrodes ELT2 for other adjacent sub-pixels SPX.

The hole layer EHL may be disposed on the first electrode ELT1, the pixel defining layer PDL, and the passivation layer PSV. At least a portion of the hole layer EHL may be disposed between the emission layer EML and the first electrode ELT1. At least another portion of the hole layer EHL may be disposed between the connecting electrode COE and the electron layer EEL.

A portion of the hole layer EHL may be connected (e.g., electrically connected) to the first electrode ELT1. Another portion of the hole layer EHL may be connected (e.g., electrically connected) to the connecting electrode COE.

The hole layer EHL may be connected (e.g., electrically connected) to the first electrode ELT1. In an embodiment, the hole layer EHL may contact a portion of the first electrode ELT1 that does not contact the pixel defining layer PDL.

The hole layer EHL may be connected (e.g., electrically connected) to the portion of the connecting electrode COE that is exposed from the pixel defining layer PDL. For example, the hole layer EHL may be disposed on a surface of the connecting electrode COE. For example, the hole layer EHL may contact the third connecting electrode COE3.

The hole layer EHL may be disconnected based on an end portion (or an edge area) of the connecting electrode COE that is exposed from the pixel defining layer PDL. As described above, the connecting electrode COE may be disposed in the protrusion area PRA of the passivation layer PSV and may form the protrusion TA. For example, with regard to the formation of the hole layer EHL, a portion of the hole layer EHL may be disposed on the protrusion TA, and another portion of the hole layer EHL may be disposed in the curved area CA of the passivation layer PSV that forms an under-cut structure/portion or has an under-cut shape. Hence, the portion of the hole layer EHL that is disposed on the connecting electrode COE may be spaced apart from the portion of the hole layer EHL that is disposed in the curved area CA. In an embodiment, the portion of the hole layer EHL that is disposed in the curved area CA may be spaced apart from the lower surface of the connecting electrode COE (e.g., the lower surface of the first connecting electrode COE1).

In an embodiment, an area in which the connecting electrode COE is disposed may be a boundary area between the sub-pixels SPX (e.g., the first sub-pixel SPX1 and the second sub-pixel SPX2) adjacent to each other. For example, the hole layer EHL may be disconnected in the boundary area between the sub-pixels SPX adjacent to each other. Hence, a risk of current leakage between the adjacent sub-pixels SPX may be substantially prevented from occurring. Moreover, as the hole layer EHL in accordance with an embodiment may be cut in the area between the adjacent sub-pixels SPX without performing an additional process of cutting the hole layer EHL, it is also effective in that the process may be facilitated.

Each of the emission layers EML may be disposed on the hole layer EHL. For example, the emission layers EML may be disposed on the hole layer EHL between the pixel defining layers PDL. Each emission layer EML may be disposed between the first pixel defining layer PDL1 and the second pixel defining layer PDL2.

The electron layer EEL may be disposed on the emission layer EML and the hole layer EHL. The electron layer EEL may be disposed between the emission layer EML (or the hole layer EHL) and the second electrode ELT2. The electron layer EEL may contact the hole layer EHL in an area in which the emission layer EML is not disposed.

The electron layer EEL may be disconnected based on the end portion (or the edge area) of the connecting electrode COE that is exposed from the pixel defining layer PDL. With regard to the formation of the hole layer EHL, a portion of the electron layer EEL may be disposed on the protrusion TA, and another portion of the electron layer EEL may be disposed in the curved area CA of the passivation layer PSV that forms an under-cut structure/portion or has an under-cut shape. Hence, the portion of the electron layer EEL that is disposed on the connecting electrode COE may be spaced apart from the portion of the electron layer EEL that is disposed in the curved area CA. In an embodiment, the portion of the electron layer EEL that is disposed in the curved area CA may be spaced apart from the lower surface of the connecting electrode COE (e.g., the lower surface of the first connecting electrode COE1). In an embodiment, the portion of the electron layer EEL that is disposed in the curved area CA may contact the lower surface of the connecting electrode COE.

The second electrode ELT2 may be disposed on the electron layer EEL. The second electrode ELT2 may be connected (e.g., electrically connected) to the electron layer EEL on the emission layer EML. Hence, the emission part EL may be connected (e.g., electrically connected) between the first electrode ELT1 and the second electrode ELT2.

The second electrode ELT2 may be disconnected based on the end portion (or the edge area) of the connecting electrode COE that is exposed from the pixel defining layer PDL. With regard to the formation of the second electrode ELT2, a portion of the second electrode ELT2 may be disposed on the protrusion TA, and another portion of the second electrode ELT2 may be disposed in the curved area CA of the passivation layer PSV that forms an under-cut structure/portion or has an under-cut shape. Hence, the portion of the second electrode ELT2 that is disposed on the connecting electrode COE may be spaced apart from the portion of the second electrode ELT2 that is disposed in the curved area CA.

The second electrode ELT2 may be connected (e.g., electrically connected) to the connecting electrode COE. The second electrode ELT2 may be connected (e.g., electrically connected) to a side surface of the connecting electrode COE. For example, the second electrode ELT2 may contact the side surface of the connecting electrode COE. In an embodiment, the second electrode ELT2 may be connected (e.g., electrically connected) to the first connecting electrode COE1. The second electrode ELT2 may contact the first connecting electrode COE1. The second electrode ELT2 may be connected (e.g., electrically connected) to the second connecting electrode COE2. The second electrode ELT2 may contact the second connecting electrode COE2.

In an embodiment, the second electrode ELT2 may be cut in the boundary area between the sub-pixels SPX adjacent to each other. Experimentally, as the second electrode ELT2 to which a cathode signal may be applied is disposed on a relatively large surface, an IR drop shape (e.g., a voltage drop phenomenon) may occur in areas in the display area DA. For example, there is the possibility of deterioration in display quality of the display device DD. However, in accordance with an embodiment, as the second electrode ELT2 is cut in some areas (e.g., a boundary area between the sub-pixels SPX), the resistance in the display area DA may be uniformly formed, so that the IR drop phenomenon may be prevented from occurring. Consequently, the display quality of the display device DD may be enhanced. Moreover, as the second electrode ELT2 in accordance with an embodiment may be cut in the area between the adjacent sub-pixels SPX without performing an additional process of cutting the second electrode ELT2, it is also effective in that the process may be facilitated.

Furthermore, in an embodiment, the under-cut structure/portion that is formed by the connecting electrode COE and the passivation layer PSV may separate the corresponding hole layers EHL from each other, and may also separate the corresponding second electrodes ELT2 from each other. For example, in an embodiment, structural characteristics, which are implemented by separate processes, may be implemented by a single process.

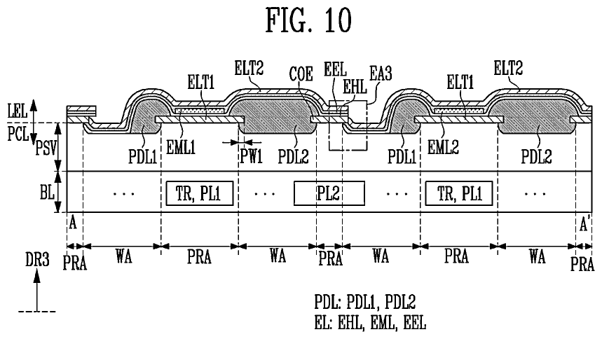

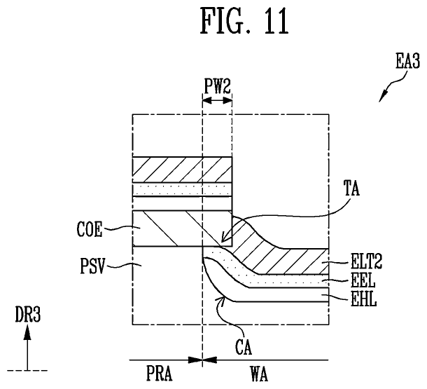

A display device DD in accordance with a second embodiment will be described with reference to FIGS. 10 and 11. Descriptions, which are same as (or similar to) those of the embodiments described above will be simplified, or may not be repeated for descriptive convenience.

FIGS. 10 and 11 illustrate the display device DD in accordance with the second embodiment. FIGS. 10 and 11 are schematic sectional views taken along line A-A′ of FIG. 5, and illustrate a structure in accordance with a second embodiment. FIG. 11 is a schematic enlarged view of area EA3 of FIG. 10.

FIG. 10 schematically illustrates layers disposed under the passivation layer PSV in the pixel circuit layer PCL as a bottom layer BL.

The display device DD in accordance with the second embodiment is different from the display device DD in accordance with the first embodiment in that the connecting electrode COE and the first electrode ELT1 are fabricated into a single layer.

In an embodiment, the connecting electrode COE and the first electrode ELT1 may have a single layer structure. In an embodiment, the connecting electrode COE and the first electrode ELT1 may include material which is patterned by dry etching.

For example, the connecting electrode COE and the first electrode ELT1 may include transparent conductive oxide, which is material having a relatively high work function capable of readily injecting holes into the emission layer EML, and which also is patterned by dry etching. For example, the connecting electrode COE and the first electrode ELT1 may include indium tin oxide (ITO).

In accordance with an embodiment, the first electrode ELT1, the connecting electrode COE, and the passivation layer PSV may be performed by the same dry etching process. For example, a dry etching process of patterning the first electrode ELT1 and the connecting electrode COE and a dry etching process of patterning the passivation layer PSV may be performed by the same process (or successive processes). Hence, there is a technical effect of facilitation of the process.

In the same manner as the previous embodiments, in an embodiment, as the hole layer EHL, the electron layer EEL, and the second electrode ELT2 may be cut on the end portion (or the edge area) of the connecting electrode COE, risks of IR drop and current leakage may also be prevented from occurring.

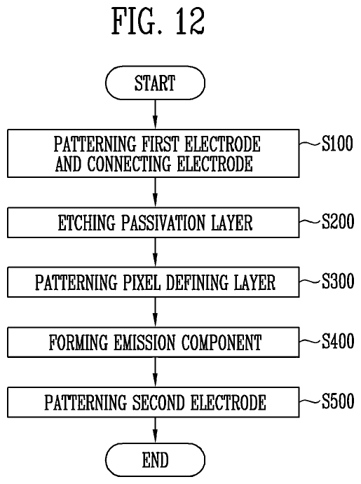

A method of fabricating the display device DD in accordance with an embodiment will be described with reference to FIGS. 12 to 18. Descriptions, which are same as (or similar to) those of the embodiments described above will be simplified, or may not be repeated for descriptive convenience.

Hereinafter, the method will be described with reference to the drawings, based on the first embodiment, and the following descriptions pertaining to the first embodiment may be applied to the second embodiment in a similar manner. In descriptions pertaining to the second embodiment, differences from the first embodiment will be described.

FIG. 12 is a flowchart illustrating a method of fabricating the display device in accordance with an embodiment.

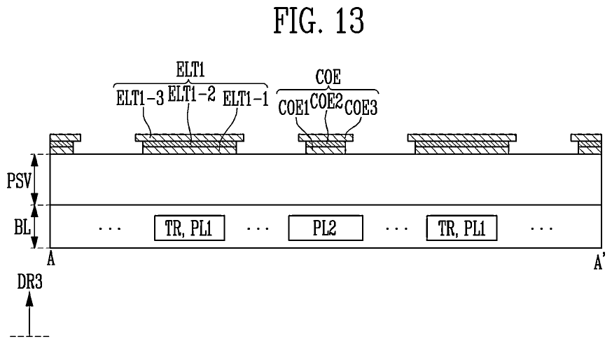

FIGS. 13 to 18 are schematic sectional views illustrating, by processes, the method of fabricating the display device in accordance with an embodiment.

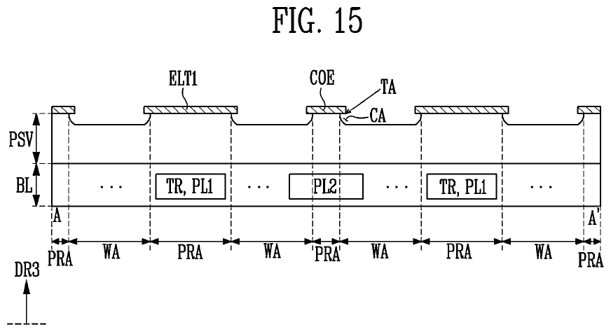

FIGS. 13, 14, and 16 to 18 are sectional views illustrating the method of fabricating the display device DD in accordance with the first embodiment. FIG. 15 is a sectional view illustrating a method of fabricating the display device DD in accordance with the second embodiment.

Referring to FIG. 12, the method of fabricating the display device DD in accordance with an embodiment may include a step S100 of patterning the first electrode and the connecting electrode, a step S200 of etching the passivation layer, a step S300 of patterning the pixel defining layer, a step S400 of forming the emission part, and a step S500 of forming the second electrode.

Referring to FIGS. 12 and 13, in the step S100 of patterning the first electrode and the connecting electrode, a base electrode for patterning the first electrode ELT1 and the connecting electrode COE may be formed (or deposited) on the passivation layer PSV, and the first electrode ELT1 and the connecting electrode COE may be fabricated by etching the formed base electrode.

In an embodiment, before the first electrode ELT1 and the connecting electrode COE are patterned, the bottom layer BL may be fabricated, and the passivation layer PSV may be formed (or deposited) on the bottom layer BL. For example, to fabricate the bottom layer BL, the base layer BSL may be provided, two or more conductive layers and insulating layers may be formed, and the driving transistor TR, the first power line PL1, and the second power line PL2 may be patterned. In an embodiment, components to be disposed on the base layer BSL may be formed through a typical patterning process (e.g., a photolithography process or the like) by using a mask.

In the step S100, the passivation layer PSV may be a via layer including organic material, and the first electrode ELT1 and the connecting electrode COE may be separated from the bottom layer BL.

In the step S100, to form the first electrode ELT1 and the connecting electrode COE in a multilayer structure, two or more electrode layers may be successively deposited and etched. For example, after a first base electrode, a second base electrode, and a third base electrode are successively deposited, the first base electrode, the second base electrode, and the third base electrode may be patterned by two or more etching processes.

In an embodiment, the first base electrode may be a conductive layer provided to fabricate the 1-1-th electrode ELT1-1 and the first connecting electrode COE1. The second base electrode may be a conductive layer provided to fabricate the 1-2-th electrode ELT1-2 and the second connecting electrode COE2. The third base electrode may be a conductive layer provided to fabricate the 1-3-th electrode ELT1-3 and the third connecting electrode COE3. The first base electrode and the third base electrode each may include transparent conductive oxide. The second base electrode may include reflective material.

In the step S100, according to the material of each of the base electrodes, a dry etching process for the first base electrode, the second base electrode, and the third base electrode may be performed and, thereafter, a wet etching process for the second base electrode may be performed. It may be desirable that, in the case where the second base electrode include silver (Ag) or aluminum (Al) as the reflective material, the wet etching process is used. It may be desirable that, in the case where the first base electrode and the third base electrode include ITO or the like as the transparent conductive oxide, the dry etching process is used.

In an embodiment, the third base electrode may have a thickness greater than that of the first base electrode. For example, the 1-3-th electrode ELT1-3 and the third connecting electrode COE3 may relatively have a further protruding structure after the dry etching process is performed.

In an embodiment, in case that the first electrode ELT1 is deposited, the first electrode ELT1 may be connected (e.g., electrically connected) to the driving transistor TR through a hole passing through the passivation layer PSV. In an embodiment, in case that the connecting electrode COE is deposited, the connecting electrode COE may be connected (e.g., electrically connected) to the second power line PL2 through a hole passing through the passivation layer PSV.

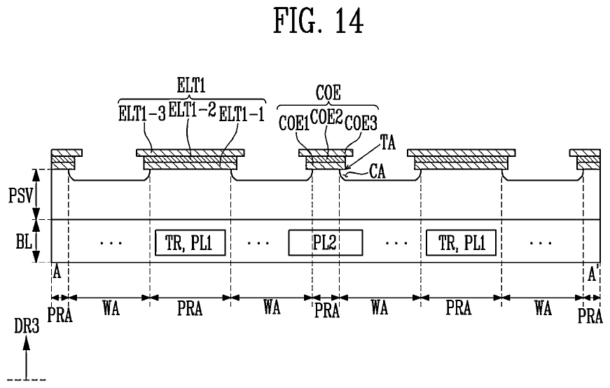

Referring to FIGS. 12 and 14, in the step S200 of etching the passivation layer, the well area WA and the protrusion area PRA may be formed by removing at least a portion of the passivation layer PSV.

In the step S200, as a partial area of the passivation layer PSV, at least a portion of an area which does not overlap the first electrode ELT1 and the connecting electrode COE may be removed. For example, in the case where the passivation layer PSV includes organic material, the dry etching process may be used.

In the step S200, the first electrode ELT1 and the passivation layer PSV may form an under-cut structure/portion or may have an under-cut shape. At least a portion of the passivation layer PSV disposed under the first electrode ELT1 may be removed. Hence, at least a portion of the lower surface of the first electrode ELT1 may be exposed.

In the step S200, the connecting electrode COE and the passivation layer PSV may form an under-cut structure/portion or may have an under-cut shape. At least a portion of the passivation layer PSV disposed under the connecting electrode COE may be removed. Hence, at least a portion of the lower surface of the connecting electrode COE may be exposed.

In the step S200, the first electrode ELT1 and the connecting electrode COE may form the protrusion TA. In an embodiment, at least a portion of the passivation layer PSV may be recessed with respect to the end portion (or the edge area) of the first electrode ELT1 (or the connecting electrode COE), thus forming the curved area CA.

In the case of the method of fabricating the display device DD in accordance with the second embodiment (refer to FIGS. 10 and 11), the step S100 of patterning the first electrode and the connecting electrode and the step S200 of etching the passivation layer may be performed by the same dry etching process. The foregoing will be described with reference to FIGS. 12 and 15.

In the method of fabricating the display device DD in accordance with the second embodiment, a dry etching process of patterning the first electrode ELT1 and the connecting electrode COE may be performed and, sequentially, a dry etching process of removing at least a portion of the passivation layer PSV may be performed. For example, the processes may be integrated, so that the process may be facilitated, and the production cost may be reduced.

As described above, the first electrode ELT1 and the connecting electrode COE may include transparent conductive oxide so that the first electrode ELT1 and the connecting electrode COE may be patterned by the dry etching process without performing the wet etching process.

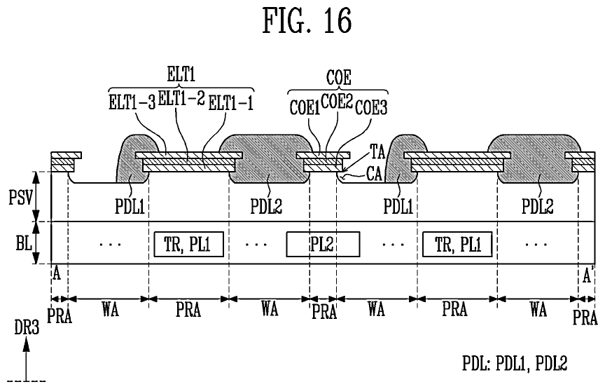

Referring to FIGS. 12 and 16, in the step S300 of patterning the pixel defining layer, the pixel defining layer PDL which exposes at least a portion of each of the first electrode ELT1 and the connecting electrode COE may be patterned.

In the step S300, the pixel defining layer PDL may expose the first electrode ELT1, so that the first electrode ELT1 may be connected (e.g., electrically connected) to the emission part EL through a subsequent process. Furthermore, the pixel defining layer PDL may expose the connecting electrode COE, so that the connecting electrode COE may maintain the under-cut structure/portion, and some of the structures deposited through a subsequent process may be cut.

In the step S300, the first pixel defining layer PDL1 may be selectively disposed on the first end portion of the first electrode ELT1, and may not cover the first end portion of the connecting electrode COE. Furthermore, the second pixel defining layer PDL2 may cover both the second end portion of the first electrode ELT1 and the second end portion of the connecting electrode COE.

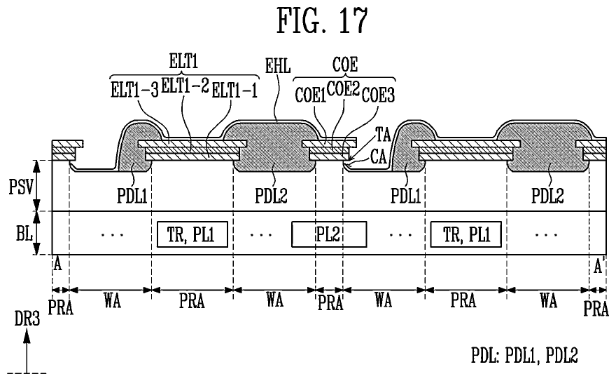

Referring to FIGS. 12 and 17, in the step S400 of forming the emission part, the hole layer EHL may be formed (or deposited).

In the step S400, the hole injection layer HIL and the hole transport layer HTL may be deposited to form the hole layer EHL.

In the step S400, the hole layer EHL may be connected (e.g., electrically connected) to the first electrode ELT1. In an embodiment, the hole layer EHL may be cut on the end portion of the connecting electrode COE that is exposed from the pixel defining layer PDL.

Hence, at least a portion of the hole layer EHL may be disposed on the connecting electrode COE, and at least another portion of the hole layer EHL may be disposed in the well area WA. As described above, the connecting electrode COE may be disposed along the edge area of the sub-pixel SPX, so that the hole layer EHL may form an end portion on the edge area of the sub-pixel SPX.

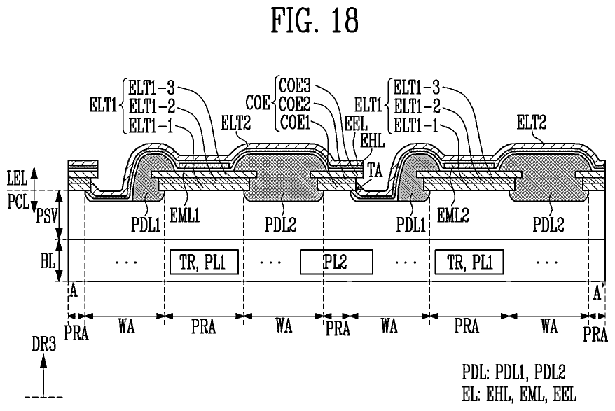

Referring to FIGS. 12 and 18, in the step S400 of forming the emission part, the emission layer EML and the electron layer EEL may be formed (or deposited).

In the step S400, the emission layer EML may be disposed on the first electrode ELT1 that is exposed from the pixel defining layer PDL. To form the electron layer EEL, the electron injection layer EIL and the electron transport layer ETL may be deposited. The emission part EL which is connected (e.g., electrically connected) to the first electrode ELT1 may be fabricated.

In the step S400, at least a portion of the electron layer EEL may be disposed on the connecting electrode COE, and at least another portion of the electron layer EEL may be disposed in the well area WA. As described above, the connecting electrode COE may be disposed along the edge area of the sub-pixel SPX, so that the electron layer EEL may form an end portion on the edge area of the sub-pixel SPX.

Referring to FIGS. 12 and 18, in the step S500 of forming the second electrode, the second electrode ELT2 may be formed (or deposited).

In the step S500, the second electrode ELT2 may be connected (e.g., electrically connected) to the emission part EL.

In the step S500, at least a portion of the second electrode ELT2 may be disposed on the connecting electrode COE, and at least another portion of the second electrode ELT2 may be disposed in the well area WA.

In the step S500, the second electrode ELT2 may include conductive material, which is inorganic material, so that a deposition incident angle thereof may be greater than that of the electron layer EEL including organic material. Therefore, the second electrode ELT2 may be disposed at an upper side compared to the electron layer EEL in the curved area CA, so that the second electrode ELT2 may cover the electron layer EEL and contact the side surface of the connecting electrode COE that is disposed at a relatively upper side.

As described above, the connecting electrode COE may be disposed along the edge area of the sub-pixel SPX, so that the second electrode ELT2 may form an end portion on the edge area of the sub-pixel SPX. The second electrode ELT2 that is disposed in the well area WA may be connected (e.g., electrically connected) to the side surface of the connecting electrode COE. Consequently, the second electrode ELT2 may be connected (e.g., electrically connected) to the adjacent connecting electrodes COE, and may be spaced apart from the second electrode ELT2 of another adjacent sub-pixel SPX.

Various embodiments may provide a display device and a method of fabricating the display device, capable of improving the display quality and enhancing the process efficiency, so that the process cost may be reduced.

In concluding the detailed description, those skilled in the art will appreciate that many variations and modifications may be made to the embodiments without substantially departing from the principles and spirit and scope of the disclosure. Therefore, the disclosed embodiments are used in a generic and descriptive sense only and not for purposes of limitation.

What is claimed is:

1. A display device, comprising:
a pixel circuit layer comprising:
a base layer,
a pixel circuit disposed on the base layer, and
a passivation layer disposed on the pixel circuit, the passivation layer comprising a well area and a protrusion area; and
a light-emitting-element layer disposed on the pixel circuit layer, the light-emitting-element layer comprising:
a light emitting element comprising:
a first electrode,
a second electrode, and
an emission part between the first electrode and the second electrode, and
a connecting electrode, wherein
the connecting electrode is disposed on the protrusion area, and
at least a portion of the connecting electrode overlaps the well area in a plan view and does not contact the passivation layer,
the emission part comprises:
a hole layer,
an electron layer, and
an emission layer provided between the hole layer and the electron layer,
the hole layer electrically connects the first electrode and the emission layer to each other,
the electron layer electrically connects the second electrode and the emission layer to each other, and
each of the hole layer and the second electrode has an end portion on the connecting electrode.

2. The display device of claim 1, wherein
the first electrode is an anode electrode,
the second electrode is a cathode electrode,
the pixel circuit comprises a first power line and a second power line,
the pixel circuit is electrically connected to the first power line and the first electrode, and
the connecting electrode is electrically connected to the second electrode and the second power line.

3. The display device of claim 2, wherein the second power line is electrically connected to the connecting electrode through a contactor formed in the passivation layer.

4. The display device of claim 2, further comprising:
a display area and a non-display area, wherein
the second power line is disposed in the non-display area, and
a portion of the connecting electrode is disposed in a perimeter of the display area, and is electrically connected to the second power line.

5. The display device of claim 1, wherein
the hole layer comprises a hole injection layer and a hole transport layer, and
the electron layer comprises an electron injection layer and an electron transport layer.

6. The display device of claim 1, wherein
the emission layer comprises:
a first emission layer forming a first sub-pixel, and
a second emission layer forming a second sub-pixel, and
the connecting electrode is disposed in a boundary area between the first sub-pixel and the second sub-pixel.

7. The display device of claim 6, wherein
a first portion of the connecting electrode surrounds the first emission layer,
a second portion of the connecting electrode surrounds the second emission layer, and
the first portion and the second portion of the connecting electrode are integral with each other.

8. The display device of claim 1, wherein the connecting electrode has a mesh shape, and forms a closed loop surrounding an area.

9. The display device of claim 6, wherein
the light-emitting-element layer comprises a pixel defining layer covering the first electrode and at least a portion of the connecting electrode, and
the pixel defining layer exposes a portion of the connecting electrode that is disposed in a peripheral portion of the emission layer, and covers another portion of the connecting electrode.

10. The display device of claim 9, wherein
the pixel defining layer comprises a first pixel defining layer and a second pixel defining layer,
the first pixel defining layer covers an end portion of the first electrode of the second sub-pixel, and exposes an end portion of the connecting electrode, and
the second pixel defining layer covers an end portion of the first electrode of the first sub-pixel, and covers another end portion of the connecting electrode.

11. The display device of claim 10, wherein the second pixel defining layer has a width greater than a width of the first pixel defining layer.

12. The display device of claim 9, wherein at least a portion of a lower surface of the connecting electrode contacts the pixel defining layer.

13. The display device of claim 1, wherein
the protrusion area surrounds at least a portion of the well area, and
the protrusion area comprises:
a first protrusion area in which the first electrode is disposed, and
a second protrusion area in which the connecting electrode is disposed.

14. The display device of claim 1, wherein
the connecting electrode comprises a protrusion,
the protrusion overlaps the well area in a plan view, and
the passivation layer forms a curved area overlapping the protrusion in a plan view.

15. The display device of claim 14, wherein
at least a portion of the hole layer is disposed on the protrusion, and
at least another portion of the hole layer is disposed in the curved area that overlaps the protrusion in a plan view.

16. The display device of claim 14, wherein
at least a portion of the electron layer is disposed on the protrusion, and
at least another portion of the electron layer is disposed in the curved area that overlaps the protrusion in a plan view.

17. The display device of claim 14, wherein
at least a portion of the second electrode is disposed on the protrusion, and
at least another portion of the second electrode is disposed in the curved area that overlaps the protrusion in a plan view.

18. The display device of claim 14, wherein the electron layer disposed in the curved area covers the hole layer.

19. The display device of claim 17, wherein the second electrode is electrically connected to a side surface of the connecting electrode.

20. The display device of claim 19, wherein
the first electrode comprises a 1-1-th electrode, a 1-2-th electrode, and a 1-3-th electrode, and
the second electrode contacts the 1-2-th electrode.

21. The display device of claim 20, wherein the 1-3-th electrode protrudes longer than the 1-1-th electrode and the 1-2-th electrode.

22. The display device of claim 20, wherein
each of the 1-1-th electrode and the 1-3-th electrode comprises transparent conductive oxide,
the 1-2-th electrode comprises a reflective material,
the 1-1-th electrode is disposed on a surface of the 1-2-th electrode, and
the 1-3-th electrode is disposed on another surface of the 1-2-th electrode.

23. The display device of claim 19, wherein the first electrode is formed has a single layer comprising transparent conductive oxide.

24. A display device comprising:
sub-pixels comprising a first sub-pixel and a second sub-pixel, wherein
each of the first sub-pixel and the second sub-pixel comprises:
a pixel circuit layer comprising:
a base layer,
a pixel circuit disposed on the base layer, and
a passivation layer disposed on the pixel circuit; and
a light-emitting-element layer disposed on the pixel circuit layer, the light-emitting-element layer comprising:
a light emitting element comprising:
a first electrode,
a second electrode, and
an emission part between the first electrode and the second electrode,
a pixel defining layer comprises:
a first pixel defining layer, and
a second pixel defining layer, and
a connecting electrode,
the emission part comprises:
a first emission part in the first sub-pixel, and
a second emission part in the second sub-pixel,
the connecting electrode is disposed between the first emission part and the second emission part,
the first pixel defining layer covers an end portion of the first electrode in the second emission part, and exposes an end portion of the connecting electrode, and
the second pixel defining layer covers an end portion of the first electrode in the first emission part, and another end portion of the connecting electrode.

25. A method of fabricating a display device, the method comprising:
forming a passivation layer on a bottom layer comprising a pixel circuit;
patterning a first electrode and a connecting electrode on the passivation layer;
etching the passivation layer;
patterning a pixel defining layer on the first electrode and the connecting electrode;
forming an emission part; and
forming a second electrode on the emission part, wherein
the patterning of the pixel defining layer comprises exposing at least a portion of each of the first electrode and the connecting electrode from the pixel defining layer, and
the etching of the passivation layer comprises exposing at least a portion of a lower surface of the connecting electrode.

26. The method of claim 25, wherein
the etching of the passivation layer comprises forming a well area and a protrusion area of the passivation layer, and
the well area includes an under-cut portion on the lower surface of the connecting electrode.

27. The method of claim 25, wherein
the emission part comprises:
a hole layer,
an electron layer, and
an emission layer between the hole layer and the electron layer,
the emission layer comprises:
a first emission layer forming a first sub-pixel, and
a second emission layer forming a second sub-pixel, and
the patterning of the pixel defining layer comprises:
patterning a first pixel defining layer; and
patterning a second pixel defining layer,
the first pixel defining layer covers an end portion of the first electrode of the second sub-pixel, and exposes an end portion of the connecting electrode, and
the second pixel defining layer covers an end portion of the first electrode of the first sub-pixel, and covers another end portion of the connecting electrode.

28. The method of claim 25, wherein
the forming of the emission part comprises:
depositing a hole layer;
patterning an emission layer on the hole layer; and
depositing an electron layer, and
the depositing of the hole layer comprises cutting the hole layer on an end portion of the connecting electrode.

29. The method of claim 25, wherein the forming of the second electrode comprises cutting the second electrode on an end portion of the connecting electrode.

30. The method of claim 25, wherein
the first electrode comprises:
a 1-1-th electrode,
a 1-2-th electrode on the 1-1-th electrode, and
a 1-3-th electrode on the 1-2-th electrode,
the connecting electrode comprises:
a first connecting electrode,
a second connecting electrode on the first connecting electrode, and
a third connecting electrode on the second connecting electrode,
the 1-1-th electrode and the first connecting electrode are formed by a same process,
the 1-2-th electrode and the second connecting electrode are formed by a same process,
the 1-3-th electrode and the third connecting electrode are formed by a same process,
each of the 1-1-th electrode, the 1-3-th electrode, the first connecting electrode, and the third connecting electrode comprises transparent conductive oxide, and
each of the 1-2-th electrode and the second connecting electrode comprises a reflective material.

31. The method of claim 30, wherein
the 1-3-th electrode has a thickness greater than a thickness of the 1-1-th electrode,
the third connecting electrode has a thickness greater than a thickness of the first connecting electrode, and
the third connecting electrode protrudes longer than the second connecting electrode.

32. The method of claim 25, wherein
each of the first electrode and the connecting electrode comprises transparent conductive oxide and does not comprise a reflective material, and
a dry etching process of the patterning of the first electrode and the connecting electrode and a dry etching process of removing at least a portion of the passivation layer are successively performed.
